(19) United States
(12) Patent Application Publication
(10) Pub. No.: US 2024/0006299 A1
(43) Pub. Date: Jan. 4, 2024

(54) SINX BASED SURFACE FINISH ARCHITECTURE

(71) Applicant: Intel Corporation, Santa Clara, CA (US)

(72) Inventors: Suddhasattwa Nad, Chandler, AZ (US); Jason Steill, Phoenix, AZ (US); Yi Yang, Gilbert, AZ (US); Brandon C. Marin, Gilbert, AZ (US); Srinivas Venkata Ramanuja Pietambaram, Chandler, AZ (US); Marcel Arlan Wall, Phoenix, AZ (US); Gang Duan, Chandler, AZ (US); Jeremy D. Ecton, Gilbert, AZ (US)

(21) Appl. No.: 17/855,568

(22) Filed: Jun. 30, 2022

(51) Int. Cl. H01L 23/498; H01L 21/48

(52) U.S. Cl. CPC H01L 23/49894; H01L 23/49816; H01L 23/49838; H01L 23/49833; H01L 23/49822; H01L 21/4857

(57) ABSTRACT

Disclosed herein are microelectronics package architectures utilizing SiNx based surface finishes and methods of manufacturing the same. The microelectronics packages may include a core material, a first plurality of pads, and a silicon nitride layer. The first plurality of pads are attached to the core material. The silicon nitride layer is attached to the core material. The silicon nitride material defines respective openings to expose at least a portion of each of the first plurality of pads.

### FIELD OF THE DISCLOSURE

The present subject matter relates to microelectronics packages. More specifically, the present disclosure relates to microelectronics package architectures utilizing SiNx based surface finishes and methods of manufacturing the same.

### BACKGROUND

Off-package input/output (I/O) bandwidth has been steadily increasing over the years. Packaging and I/O technologies need to scale to meet this bandwidth demand. As a result, package pin counts and I/O data rates have continued to increase. However, electrical I/O reach (length of electrical printed circuit board (PCB) trace or cable) continues to reduce as data rates increase. Additionally, I/O energy efficiency improvement has drastically slowed, which has resulted in a quickly approaching I/O power wall for high-performance packages.

### BRIEF DESCRIPTION OF THE FIGURES

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1A shows a microelectronics package in accordance with at least one example of this disclosure.

FIG. 1B shows a detail of the microelectronics package in FIG. 1A in accordance with at least one example of this disclosure.

FIGS. 2A and 2B show a process for creating a SiNx protected surface routed HSIOs without the application of solder resist layers in accordance with at least one example of this disclosure.

FIG. 3 shows system level diagram in accordance with at least one example of this disclosure.

### DETAILED DESCRIPTION

Various architectures may require the enabling of high speed input/out (HSIO) and fine line features on metal layers. For example, the architectures may require fine lines on the last metal layer under a solder resist surface. As such smooth copper may be needed on this layer while integrating with the first level interconnect (FLI) surface finish.

Previous solutions use solder resist (SR) to protect copper surfaces and provide openings to access the surface finish and for ball attachment. As disclosed herein, solder resist layers can be made redundant by using a silicon nitride, SiNx, film application. As disclosed herein, SiNx films may simultaneously provide a smooth copper interface for surface routed HSIOs as well as a protection layer. Solder resist lamination layers can thus be eliminated resulting in a cheaper, thinner, and more capable substrate package. For example, by eliminating the solder resist layers, roughing of copper or other layers may be avoided since the SiNx films do not require a roughened surface to adhere to.

Use of SiNx may enable smooth copper features for surface routed HSIOs. Use of SiNx layers may also lower the manufacturing cost of a substrate package with surface routed HSIOs. For example, because surfaces do not need to be roughed for the SiNx layers to be attached or otherwise formed on them, at least one process step, a roughing step, may be eliminated, thereby reducing costs and simplifying the manufacturing process. In addition, the using of SiNx layers results in a smaller Z-height, delivering thinner substrate packages and/or allowing more substrate packages to fit into a give space.

As disclosed herein, the use of SiNx layers results in a unique surface architecture. The surface architecture may be identifiable by the absence of solder resist and the presence of a SiNx film on the final metal layer as disclosed herein. For example, a unique surface architecture results when the SiNx film disclosed herein is used and is identifiable by simple cross-section and microscope inspection. Additionally, standard surface chemical analysis techniques (EDX, XPS, etc.) may be used to identify the SiNx film.

As disclosed herein, a microelectronics package may include a core material and traces and pads may be attached to the core material. A silicon nitride layer may be attached to the core material and partially cover portions of the pads and/or traces. For example, the silicon nitride material may define respective openings to expose at least a portion of each of the first plurality of pads.

In some example embodiments, the silicon nitride layer may have a thickness of approximately 50 microns. In some example embodiments, the silicon nitride layer may have a thickness less then 50 microns. Each of the plurality of pads may have a surface roughness on the order of nanometers. As disclosed herein, microelectronics packages using the SiNx film do not contain a solder resist material proximate the silicon nitride layer.

The above discussion is intended to provide an overview of subject matter of the present patent application. It is not intended to provide an exclusive or exhaustive explanation. The description below is included to provide further information.

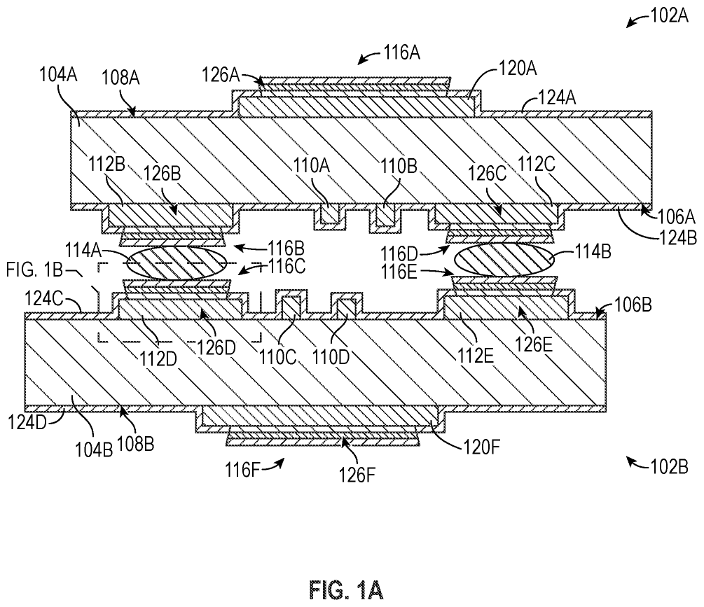

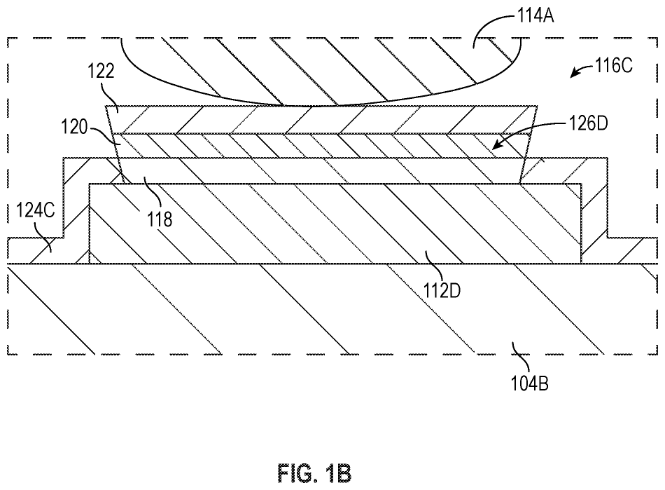

Turning now to the figures, FIG. 1A shows a microelectronics package 100 in accordance with at least one example of this disclosure. Microelectronics package 100 may include stacked layers 102 (labeled individually as stacked layers 102A and 102B. While FIG. 1A shows only two stacked layers, microelectronics package 100 may include any number of stacked layers 102.

Each of stacked layers 102 may include a core material 104 (labeled individually as core material 104A and 104B). Core materials 104 may be any substrate material such as organic and inorganic substrates. Core materials 104 may have first surfaces 106 (labeled individually as first surfaces 106A and 106B) and second surfaces 108 (labeled individually as second surfaces 108A and 108B).

As disclosed herein, traces 110 (labeled individually as traces 110A, 110B, 110C, and 110D) may be attached to first surfaces 106 and second surfaces 108. Pads 112 (labeled individually as pads 112A, 112B, 112C, 112D, 112E, and 112F) may be attached to first surfaces 106 and second surfaces 108. As disclosed herein, solder balls 114 (labeled individually as solder balls 114A and 114B) may form electrical connections between traces 110 and pads 112 of respective stacked layers 102.

As disclosed herein, electroless nickel electroless palladium immersion gold (ENEPIG) structures 116 (labeled individually as ENEPIG structures 116A, 116B, 116C, 116D, 116E, and 116F) may be formed on pads 112. ENEPIG structures 116 provide protection for pads 112, which may be formed of a metal, such as copper.

FIG. 1B shows a detail of microelectronics package 100 in FIG. 1A in accordance with at least one example of this disclosure. As shown in FIG. 1B, ENEPIG structure 116C, as well as each of ENEPIG structures 116, include a nickel layer 118, a palladium layer 120, and a gold layer 122. Nickel layer 118 may act as a barrier layer to prevent pads 112, which may be copper, from interacting with other metals, such as gold. Nickel layer 118 has a thickness that is between 3.0 to 5.0 microns.

Palladium layer 120 is what differentiates ENEPIG from electroless nickel electroless gold (ENEG) surface finish technology, acts as another barrier layer. Palladium layer 120 may prevent nickel layer 118 from corroding and diffusing into gold layer 122. Palladium layer 120 has a thickness of 0.05 to 0.1 microns, depending on the application.

Gold layer 122 is the final layer added to ENEPIG surfaces and has the benefits of low contact resistance, protection from friction, and resistance to oxidation. Gold layer 122 also preserves palladium layer 120's solderability. Gold layer 122 has a thickness of between and 0.05 microns.

As disclosed herein, silicon nitride layers 124 (labeled individually as silicon nitride layers 124A, 124B, 124C, and 124D) may be formed on surfaces, such as first surface 106A and second surfaces 106B, of core materials 104. Silicon nitride layers 124 may define one or more respective openings 126 (labeled as openings 126A, 126B, 126C, 126D, 126E, and 126F) that allow respective ENEPIG structures 116 to pass through silicon nitride layers 124 to reach pads 112.

Silicon nitride layers 124 may be any silicon nitrogen based compound and may have a thickness of approximately 50 microns or less than 50 microns. As disclosed herein, silicon nitride layers 124, sometimes referred to as SiNx films, are applied to the final metal layers, such as such as surfaces of core materials 104, traces 110, and pads 112 before a patterning process, such as dry film resist (DFR) patterning. Silicon nitride layers 124 may mimic build-up layers in traditional packaging.

As disclosed herein, the silicon nitride layers 124 are thinner than typical solder resist layers. The result is that for a given number of stacked layers 102, the Z height is smaller than the same number of stacked layers that utilize typical solder resist layers. The result, is that more stacked layers 102 can fit within a given height or a given number of stacked layers 102 may occupy a smaller space.

As disclosed herein, silicon nitride layers 124 do not require rough surfaces, which may be required for solder resist to attach to core materials and copper traces and pads. Smoother copper surfaces provide for better electrical performance. The result is that the SiNx surface architectures disclosed herein provide enhanced computing power within microelectronics package 100 constructing using traditional solder resist layer technology.

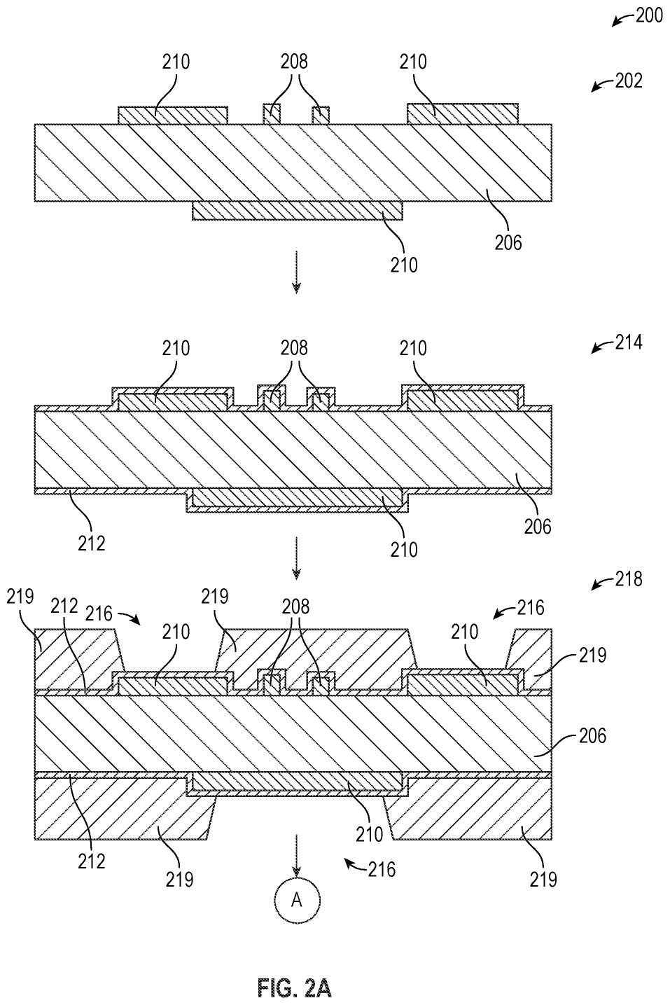

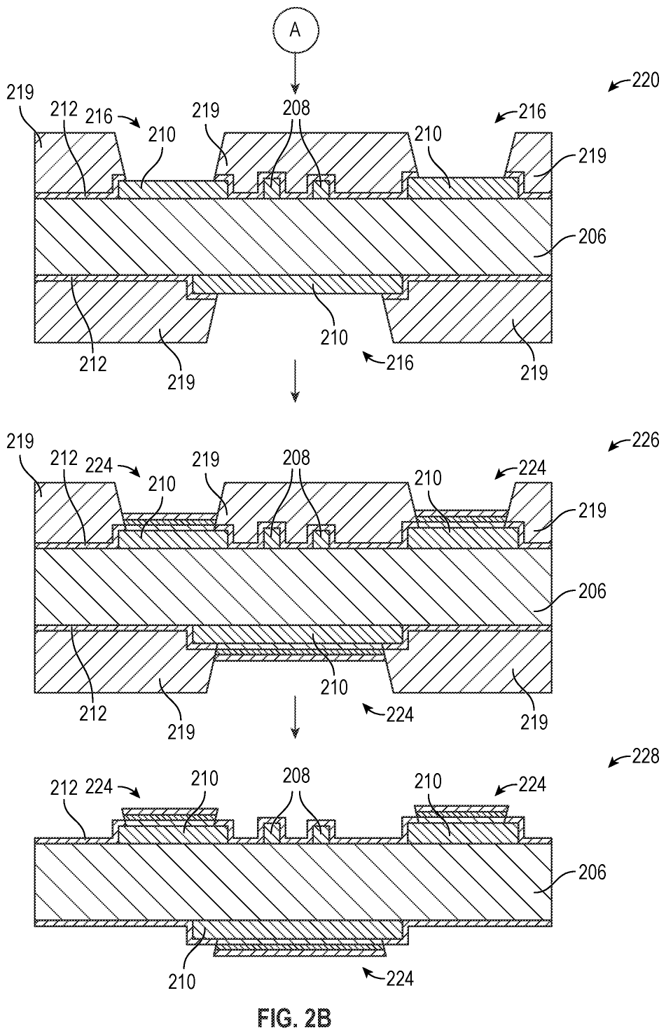

FIGS. 2A and 2B shows a process flow 200 for creating a SiNx protected surface routed HSIOs without the application of solder resist layers. Process flow 200 may begin at stage 202, where a first layer 204 is formed. First layer 204 may include a core material 206. During stage 202, traces 208 and pads 210 may be formed on surfaces of core material 206. Forming traces 208 and pads 210 may include polishing surfaces of traces 208 and pads 210. Polishing surfaces of traces 208 and pads 210 may result in smoother surfaces for improved electrical performance as disclosed herein.

Once traces 208 and pads 210 are formed, a silicon nitride layer 212 may be formed (214). Forming silicon nitride layer 212 may include sputtering a silicon nitride material onto the surfaces of core material 206 and surfaces of traces 208 and pads 210. Forming silicon nitride layer 212 may include applying a silicon nitride material onto the surfaces of core material 206 and surfaces of traces 208 and pads 210 pads via a chemical vapor deposition process. Forming silicon nitride layer 212 may include applying a silicon nitride material onto the surfaces of core material 206 and surfaces of traces 208 and pads 210 pads via a physical deposition process. Polishing the surfaces of traces 208 and pads 210 may be performed prior to depositing the silicon nitride layer.

Once the silicon nitride layer 212 is formed, a dry film resist (DRF) layer 221 may be formed and a lamination and exposure process may be used to define one or more openings 216 to be formed in silicon nitride layer 212 (218). Once the openings are defined using DFR lamination and exposure, openings 216 may be formed in the silicon nitride layer 212 (220). Forming openings 216 to expose portions of pads 210 may include etching silicon nitride layer 212 via a dry film resist and etching process. For example, dry desmear can be used to remove portions of silicon nitride layer 212. IN other examples, forming openings 216 to expose portions of pads 210 may include etching silicon nitride layer 212 via a plasma etching process.

Once openings 216 are formed in silicon nitride layer 212, surface finishes 224 can be applied to pads 210 (226). As disclosed herein, surface finishes 224 can include ENEPIG surface finishes. As part of applying surface finishes 224, a copper layer with a thickness of between 3.0 to 5.0 microns thick may be formed. A palladium layer may be deposited onto the nickel layer and have a thickness of 0.05 to 0.1 microns, depending on the application. A gold layer may be deposited on the palladium layer and have a thickness of between 0.03 and 0.05 microns, which is substantially lower than any other solution using gold plating techniques.

Once surface finishes 224 are applied, the DFR layer 219 may be removed (228). Removal of DFR layer 219 reveals a substrate with surface finished pads where the final metal layer and its surface routed HSIOs are protected by SiNx film 212. This construct can now be used for standard ball attach, hybrid copper bonding or ASOS flows.

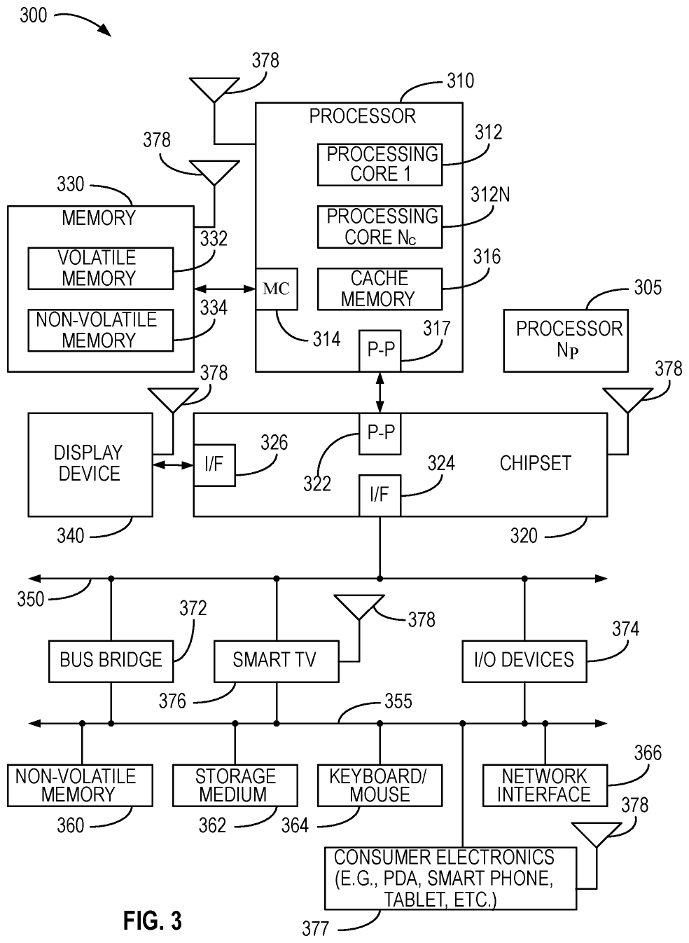

FIG. 3 illustrates a system level diagram, according to one embodiment of the invention. For instance, FIG. 3 depicts an example of an electronic device (e.g., system) including microelectronics package 100 as described herein. FIG. 3 is included to show an example of a higher-level device application for the present invention. In one embodiment, system 300 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance or any other type of computing device. In some embodiments, system 300 is a system on a chip (SOC) system.

In one embodiment, processor 310 has one or more processing cores 312 and 312N, where 312N represents the Nth processor core inside processor 310 where N is a positive integer. In one embodiment, system 300 includes multiple processors including 310 and 305, where processor 305 has logic similar or identical to the logic of processor 310. In some embodiments, processing core 312 includes, but is not limited to, pre-fetch logic to fetch instructions, decode logic to decode the instructions, execution logic to execute instructions and the like. In some embodiments, processor 310 has a cache memory 316 to cache instructions and/or data for system 300. Cache memory 316 may be organized into a hierarchal structure including one or more levels of cache memory.

In some embodiments, processor 310 includes a memory controller 314, which is operable to perform functions that enable the processor 310 to access and communicate with memory 330 that includes a volatile memory 332 and/or a non-volatile memory 334. In some embodiments, processor 310 is coupled with memory 330 and chipset 320. Processor 310 may also be coupled to a wireless antenna 378 to communicate with any device configured to transmit and/or receive wireless signals. In one embodiment, the wireless antenna interface 378 operates in accordance with, but is not limited to, the IEEE 802.11 standard and its related family, Home Plug AV (HPAV), Ultra Wide Band (UWB), Bluetooth, WiMax, or any form of wireless communication protocol.

In some embodiments, volatile memory 332 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. Non-volatile memory 334 includes, but is not limited to, flash memory, phase change memory (PCM), read-only memory (ROM), electrically erasable programmable read-only memory (EEPROM), or any other type of non-volatile memory device.

Memory 330 stores information and instructions to be executed by processor 310. In one embodiment, memory 330 may also store temporary variables or other intermediate information while processor 310 is executing instructions. In the illustrated embodiment, chipset 320 connects with processor 310 via Point-to-Point (PtP or P-P) interfaces 317 and 322. Chipset 320 enables processor 310 to connect to other elements in system 300. In some embodiments of the invention, interfaces 317 and 322 operate in accordance with a PtP communication protocol such as the Intel® QuickPath Interconnect (QPI) or the like. In other embodiments, a different interconnect may be used.

In some embodiments, chipset 320 is operable to communicate with processor 310, 305N, display device 340, and other devices 372, 376, 374, 360, 362, 364, 366, 377, etc. Chipset 320 may also be coupled to a wireless antenna 378 to communicate with any device configured to transmit and/or receive wireless signals.

Chipset 320 connects to display device 340 via interface 326. Display 340 may be, for example, a liquid crystal display (LCD), a plasma display, cathode ray tube (CRT) display, or any other form of visual display device. In some embodiments of the invention, processor 310 and chipset 320 are merged into a single SOC. In addition, chipset 320 connects to one or more buses 350 and 355 that interconnect various elements 374, 360, 362, 364, and 366. Buses 350 and 355 may be interconnected together via a bus bridge 372. In one embodiment, chipset 320 couples with a non-volatile memory 360, a mass storage device(s) 362, a keyboard/mouse 364, and a network interface 366 via interface 324 and/or 304, smart TV 376, consumer electronics 377, etc.

In one embodiment, mass storage device 362 includes, but is not limited to, a solid state drive, a hard disk drive, a universal serial bus flash memory drive, or any other form of computer data storage medium. In one embodiment, network interface 366 is implemented by any type of well known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra Wide Band (UWB), Bluetooth, WiMax, or any form of wireless communication protocol.

While the modules shown in FIG. 3 are depicted as separate blocks within the system 300, the functions performed by some of these blocks may be integrated within a single semiconductor circuit or may be implemented using two or more separate integrated circuits. For example, although cache memory 316 is depicted as a separate block within processor 310, cache memory 316 (or selected aspects of 316) can be incorporated into processor core 312.

### Additional Notes

The following, non-limiting examples, detail certain aspects of the present subject matter to solve the challenges and provide the benefits discussed herein, among others.

Example 1 is a microelectronics package comprising: a core material; a first plurality of traces on the core material; a first plurality of pads on the core material; and a layer on the core material, the layer including silicon and nitrogen, the layer defining respective openings to expose at least a portion of each of the first plurality of pads.

In Example 2, the subject matter of Example 1 optionally includes wherein the layer encapsulates the core material.

In Example 3, the subject matter of any one or more of Examples 1-2 optionally include wherein the core material has a first surface and a second surface, the first plurality of traces and the first plurality of pads attached to opposite surfaces.

In Example 4, the subject matter of any one or more of Examples 1-3 optionally include wherein the core material has a first surface and a second surface, both the first plurality of traces and the first plurality of pads attached to the first surface or the second surface.

In Example 5, the subject matter of any one or more of Examples 1˜4 optionally include microns or less.

In Example 6, the subject matter of any one or more of Examples 1-5 optionally include wherein the layer comprises silicon nitride.

In Example 7, the subject matter of any one or more of Examples 1-6 optionally include wherein each of the plurality of pads have a surface roughness on the order of nanometers.

In Example 8, the subject matter of any one or more of Examples 1-7 optionally include wherein the microelectronics package does not contain a solder resist material proximate the layer.

Example 9 is a microelectronics package comprising: a plurality of stacked layers, each of the plurality of stacked layers comprising: a core material; a first plurality of traces on the core material; a first plurality of pads on the core material; and a layer on the core material, the layer including silicon and nitrogen, the layer defining respective openings to expose at least a portion of each of the first plurality of pads.

In Example 10, the subject matter of Example 9 optionally includes wherein the core material of each of the plurality of stacked layers is encapsulates by the layer.

In Example 11, the subject matter of any one or more of Examples 9-10 optionally include wherein the first plurality of traces and the first plurality of pads are attached to opposite surfaces of a respective core material.

In Example 12, the subject matter of any one or more of Examples 9-11 optionally include wherein first plurality of traces and the first plurality of pads are attached to opposite surfaces of a respective core material.

In Example 13, the subject matter of any one or more of Examples 9-12 optionally include microns or less.

In Example 14, the subject matter of any one or more of Examples 9-13 optionally include wherein the layer comprises silicon nitride.

In Example 15, the subject matter of any one or more of Examples 9-14 optionally include wherein each of a subset of the plurality of pads have a surface roughness on the order of nanometers.

In Example 16, the subject matter of any one or more of Examples 1-15 optionally include wherein the microelectronics package does not contain a solder resist in between the plurality of stacked layers.

Example 17 is a method of manufacturing a microelectronics package, the method comprising: forming a first layer comprising a core material; forming pads on surfaces the core material; forming a layer on the core material and pads, the layer comprising silicon and nitrogen; and forming openings to expose portions of the pads.

In Example 18, the subject matter of any one or more of Examples 11-17 optionally include wherein forming the layer includes sputtering a silicon nitride material onto the surfaces of the core material and surfaces of the pads.

In Example 19, the subject matter of any one or more of Examples 11-18 optionally include wherein forming the layer includes applying a silicon nitride material onto the surfaces of the core material and surfaces of the pads via a chemical vapor deposition process.

In Example 20, the subject matter of any one or more of Examples 11-19 optionally include wherein forming the layer includes applying a silicon nitride material onto the surfaces of the core material and surfaces of the pads via a physical vapor deposition process.

In Example 21, the subject matter of any one or more of Examples 11-20 optionally include polishing surfaces of the pads.

In Example 22, the subject matter of any one or more of Examples 11-21 optionally include wherein polishing the surfaces of the pads is performed prior to depositing the layer.

In Example 23, the subject matter of any one or more of Examples 11-22 optionally include wherein forming the openings to expose the portions of the pads includes etching the layer via a plasma etching process.

In Example 24, the subject matter of any one or more of Examples 11-23 optionally include wherein forming the openings to expose the portions of the pads includes etching the layer via a dry film resist and etching process.

In Example 25, the subject matter of any one or more of Examples 11-24 optionally include stacking multiple core materials, each of the multiple core materials having pads and a silicon nitride layer.

In Example 26, the microelectronics packages, systems, apparatuses, or method of any one or any combination of Examples 1-25 can optionally be configured such that all elements or options recited are available to use or select from.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

What is claimed is:

1. A microelectronics package comprising:
a core material;
a first plurality of traces on the core material;
a first plurality of pads on the core material; and
a layer on the core material, the layer including silicon and nitrogen, the layer defining respective openings to expose at least a portion of each of the first plurality of pads.

2. The microelectronics package of claim 1, wherein the layer encapsulates the core material.

3. The microelectronics package of claim 1, wherein the core material has a first surface and a second surface, the first plurality of traces and the first plurality of pads attached to opposite surfaces.

4. The microelectronics package of claim 1, wherein the core material has a first surface and a second surface, both the first plurality of traces and the first plurality of pads attached to the first surface or the second surface.

5. The microelectronics package of claim 1, wherein the layer has a thickness of approximately 50 microns or less.

6. The microelectronics package of claim 1, wherein the layer comprises silicon nitride.

7. The microelectronics package of claim 1, wherein each of the plurality of pads have a surface roughness on the order of nanometers.

8. The microelectronics package of claim 1, wherein the microelectronics package does not contain a solder resist material proximate the layer.

9. A microelectronics package comprising:
a plurality of stacked layers, each of the plurality of stacked layers comprising:
a core material;
a first plurality of traces on the core material;
a first plurality of pads on the core material; and
a layer on the core material, the layer including silicon and nitrogen, the layer defining respective openings to expose at least a portion of each of the first plurality of pads.

10. The microelectronics package of claim 9, wherein the core material of each of the plurality of stacked layers is encapsulates by the layer.

11. The microelectronics package of claim 9, wherein the first plurality of traces and the first plurality of pads are attached to opposite surfaces of a respective core material.

12. The microelectronics package of claim 9, wherein first plurality of traces and the first plurality of pads are attached to opposite surfaces of a respective core material.

13. The microelectronics package of claim 9, wherein the layer of at least one of the plurality of stacked layers has a thickness of approximately 50 microns or less.

14. The microelectronics package of claim 9, wherein the layer comprises silicon nitride.

15. The microelectronics package of claim 9, wherein each of a subset of the plurality of pads have a surface roughness on the order of nanometers.

16. The microelectronics package of claim 1, wherein the microelectronics package does not contain a solder resist in between the plurality of stacked layers.

17. A method of manufacturing a microelectronics package, the method comprising:
forming a first layer comprising a core material;
forming pads on surfaces the core material;
forming a layer on the core material and pads, the layer comprising silicon and nitrogen; and
forming openings to expose portions of the pads.

18. The method of claim 11, wherein forming the layer includes sputtering a silicon nitride material onto the surfaces of the core material and surfaces of the pads.

19. The method of claim 11, wherein forming the layer includes applying a silicon nitride material onto the surfaces of the core material and surfaces of the pads via a chemical vapor deposition process.

20. The method of claim 11, wherein forming the layer includes applying a silicon nitride material onto the surfaces of the core material and surfaces of the pads via a physical vapor deposition process.

21. The method of claim 11, further comprising polishing surfaces of the pads.

22. The method of claim 11, wherein polishing the surfaces of the pads is performed prior to depositing the layer.

23. The method of claim 11, wherein forming the openings to expose the portions of the pads includes etching the layer via a plasma etching process.

24. The method of claim 11, wherein forming the openings to expose the portions of the pads includes etching the layer via a dry film resist and etching process.

25. The method of claim 11, further comprising stacking multiple core materials, each of the multiple core materials having pads and a silicon nitride layer.
